(19) United States
(12) Patent Application Publication
(10) Pub. No.: US 2026/0254409 A1
(43) Pub. Date: Aug. 27, 2026

(54) TUNABLE DISTRIBUTED OSCILLATOR WITH FLEXIBLE ELECTRICAL LENGTH

(71) Applicant: Marvell Asia Pte Ltd, Singapore (SG)

(72) Inventors: Tomas Alexander Dusatko, North Vancouver (CA); Waleed Elhalwagy, Kanata (CA); Stanley Siu Kee Ho, Richmond (CA); Marco Garampazzi, Pavia (IT)

(73) Assignee: Marvell Asia Pte Ltd, Singapore (SG)

(21) Appl. No.: 19/546,603

(22) Filed: Feb. 23, 2026

Related U.S. Application Data
(60) Provisional application No. 63/763,217, filed on Feb. 25, 2025.

(51) Int. Cl. H03B 5/18; H03B 5/08; H03L 7/08

(52) U.S. Cl. CPC H03B 5/18; H03B 5/08; H03L 7/0802

(57) ABSTRACT

Tunable distributed oscillators (DOs) with flexible electrical length and associated systems, components, and devices are disclosed. In one aspect, a DO may include a plurality of DO units coupled in series. An individual DO unit includes a transmission-line segment having first and second ends and a middle portion between the first end and the second end. The DO unit further includes a first oscillator coupled with the first end, a second oscillator coupled with the second end, a first inductive matching circuit coupled between the first oscillator and the middle portion, and a second inductive matching circuit coupled between the second oscillator and the middle portion. By tuning the inductance or effective reactance of the first and second inductive matching circuits, the phase response of the DO unit may be adjusted so that the effective electrical length of the transmission-line segment is shortened relative to its physical length.

### CROSS-REFERENCE TO RELATED APPLICATION

This application claims the benefit of U.S. Provisional Patent App. No. 63/763,217, entitled “Tunable Distributed Voltage Control Oscillator (DVCO) with Flexible Electrical Length,” filed on Feb. 25, 2025, the disclosure of which is expressly incorporated herein by reference in its entirety.

### BACKGROUND

An oscillator is an electronic circuit that generates a periodic oscillating signal, typically a sine wave or square wave, whose frequency can be adjusted by varying an input control parameter. For example, a Voltage-Controlled Oscillator (VCO) is a type of oscillator where the input control parameter is an applied voltage. In a VCO, the oscillation frequency is established by reactive components (e.g., capacitors and inductors) whose effective values change in response to the control voltage, thereby enabling precise and rapid frequency tuning. Oscillators are fundamental building blocks in high-speed optical communication systems because they provide tunable frequency generation for applications including phase-locked loops (PLLs), frequency synthesizers, and modulation circuitry. Oscillators are also widely used in applications other than optical communication systems. Some examples of such applications include radio frequency (RF) and microwave communication systems, wireless technologies such as 5G and satellite communication, radar systems, and test and measurement equipment.

A distributed oscillator (DO), such as a Distributed Voltage-Controlled Oscillator (DVCO), extends the general oscillator concept by distributing the resonant and gain mechanisms across multiple transmission-line segments and associated active components, rather than relying on a single lumped resonant element. This distributed architecture is particularly advantageous for high-frequency and large-scale systems, including next-generation optical physical layer (PHY) channels (optical PHYs), where transmission-line-based resonance supports higher operating frequencies and improved scalability. Because DOs are critical building blocks in modern high-speed communication systems, continued innovation and further performance improvements remain highly desirable.

### BRIEF DESCRIPTION OF THE DRAWINGS

Embodiments will be readily understood by the following detailed description in conjunction with the accompanying drawings.

FIG. 1 is a block diagram of an example optical communication system in which one or more tunable DOs with flexible electrical length may be implemented, according to an embodiment.

FIGS. 2A-2B illustrate different examples of an arrangement of channels and a PLL with an integrated tunable DO with flexible electrical length, according to various embodiments.

FIG. 3 illustrates an example of a tunable DO with two DO units, according to an embodiment.

FIGS. 4A-4B illustrate different examples of inductive matching circuits within a DO unit, according to various embodiments.

### DETAILED DESCRIPTION

Tunable DOs with flexible electrical length and associated systems, components, and devices are disclosed. The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating tunable DOs with flexible electrical length described herein, it might be useful to first understand phenomena that may come into play in some systems where DOs may be used. The following foundational information may be viewed as a basis from which the present disclosure may be properly explained. Such information is offered for purposes of explanation only and, accordingly, should not be construed in any way to limit the broad scope of the present disclosure and its potential applications.

In an optical or electrical communication system, particularly within a PHY channel, a DO operates as a key component for generating and distributing high-frequency clock signals that remain phase-aligned across multiple transmission lanes. A DO may be implemented as a plurality of DO units arranged in a daisy-chained (i.e., serially connected) configuration, with each unit contributing to the overall resonant structure and clock-distribution network. Each DO unit includes a transmission-line segment with an oscillator element positioned at each end, allowing the unit to sustain oscillation locally while also coupling energy to adjacent units. When connected in this serial configuration, the units collectively form a multi-segment resonant system in which the oscillation propagates along successive transmission-line sections. This architecture promotes phase alignment between units, enables injection locking throughout the chain, and supports scalable high-frequency clock generation for complex communication environments. The DO generates a periodic signal whose frequency can be precisely tuned by an applied control signal (e.g., a voltage), and the distributed nature of the resonant structure allows the oscillation mechanism to extend across multiple transmission-line segments and associated active components. As a result, the DO delivers synchronized clock signals to each PHY channel, supporting accurate timing for the high-speed transmission and reception of data.

Embodiments of the present disclosure are based on the recognition that, in current DO designs, the maximum achievable oscillation frequency is fundamentally constrained by the physical dimensions of the transmission line that forms the core resonant element of the oscillator. In particular, the length of the transmission line within an individual DO unit is typically dictated by the width or overall footprint of a single PHY channel. As communication systems evolve to support higher baud rates, PHY channels tend to grow in physical size to accommodate increased data throughput, tighter signal-integrity budgets, and more complex front-end circuitry. This growth drives proportionally longer transmission-line segments in the DO architecture. However, increasing the transmission-line length inherently lowers the natural resonant frequency because the standing-wave modes scale inversely with line length for a given propagation velocity and boundary condition. Consequently, existing DO implementations encounter a structural limitation: the need for longer transmission lines to service larger PHY channels directly conflicts with the requirement for higher oscillator frequencies in next-generation systems. This trade-off constrains architectural scalability, forcing designers to choose between physical integration and frequency headroom, and thereby impeding the simultaneous achievement of high data rates and high-frequency clock distribution within a unified design.

Embodiments of the present disclosure are further based on the recognition that careful circuit design may allow breaking the trade-off between physical transmission-line length and achievable oscillation frequency in transmission-line-based DOs. In particular, the disclosed embodiments place an inductive matching circuit at each end of the transmission-line segment of a DO unit. As used herein, the term “inductive matching circuit” (which may also be referred to as an “inductive matching network”) refers to a circuit or a network that includes at least one inductor, optionally combined with one or more capacitors, configured to transform impedance and introduce a controlled phase rotation at the operating frequency. By tuning inductance or effective reactance of these end networks, phase response at line terminations may be adjusted so that the effective electrical length of the transmission-line segment is shortened relative to its actual physical length. This engineered phase compensation restores the resonance condition at a higher oscillation frequency than would otherwise be permitted by the unmodified line, thereby decoupling frequency selection from the physical length of the line. As a result, the oscillator can operate at target high frequencies even when the physical transmission-line length is longer (e.g., as set by PHY-layout constraints), enabling scalable integration, improved layout flexibility, and high-speed clock distribution without sacrificing frequency performance.

In one aspect, a DO may include a plurality of DO units coupled in series. An individual DO unit includes a transmission-line segment having first and second ends and a middle portion between the first end and the second end. The DO unit further includes a first oscillator coupled with the first end, a second oscillator coupled with the second end, a first inductive matching circuit coupled between the first oscillator and the middle portion, and a second inductive matching circuit coupled between the second oscillator and the middle portion. By tuning the inductance or effective reactance of the first and second inductive matching circuits, the phase response of the DO unit may be adjusted so that the effective electrical length of the transmission-line segment is shortened relative to its physical length. Any of the oscillators described herein may be implemented using any suitable oscillator topology, including but not limited to LC resonators (e.g., cross-coupled LC, Colpitts, Hartley, Clapp, Pierce), ring oscillators (single-ended or differential, current- or voltage-starved), relaxation/RC oscillators, and crystal-based oscillators (e.g., XO, TCXO, OCXO, Pierce-crystal), as well as MEMS, SAW, or BAW resonator oscillators. In various embodiments, the oscillators may be VCOs, current-controlled oscillators (CCOs), or digitally controlled oscillators (DCOs). In some embodiments, the oscillators may be injection-locked oscillators (ILOs). In various embodiments, the oscillators may further encompass specialized high-frequency types such as dielectric resonator oscillators (DROs) or optoelectronic oscillators (OEOs). The choice of topology may be selected to meet the target operating frequency, phase-noise performance, tuning range, supply/area constraints, integration level, or compatibility with the inductive matching networks and transmission-line structures disclosed, and any such oscillator capable of sustaining the required resonance and providing the desired tuning/control characteristics may be employed within the scope of this invention.

In the following detailed description, reference is made to the accompanying drawings that form a part hereof, wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Any of the features discussed with reference to any accompanying drawings herein may be combined with any other features to form an optical communication system 100, any of the arrangements 200, a DO 300, or any of the DO units 400, as appropriate. A number of elements of the drawings with the same reference numerals may be shared between different drawings; for ease of discussion, a description of these elements provided with respect to one of the drawings is not repeated for the other drawings, and these elements may take the form of any of the embodiments disclosed herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “transmitter module” and “transmitter” are synonymous and may be used interchangeably herein, as are the terms “receiver module” and “receiver,” the terms “inductive matching circuit” and “inductive matching network,” and the terms “transmission line” and “transmission-line segment.”

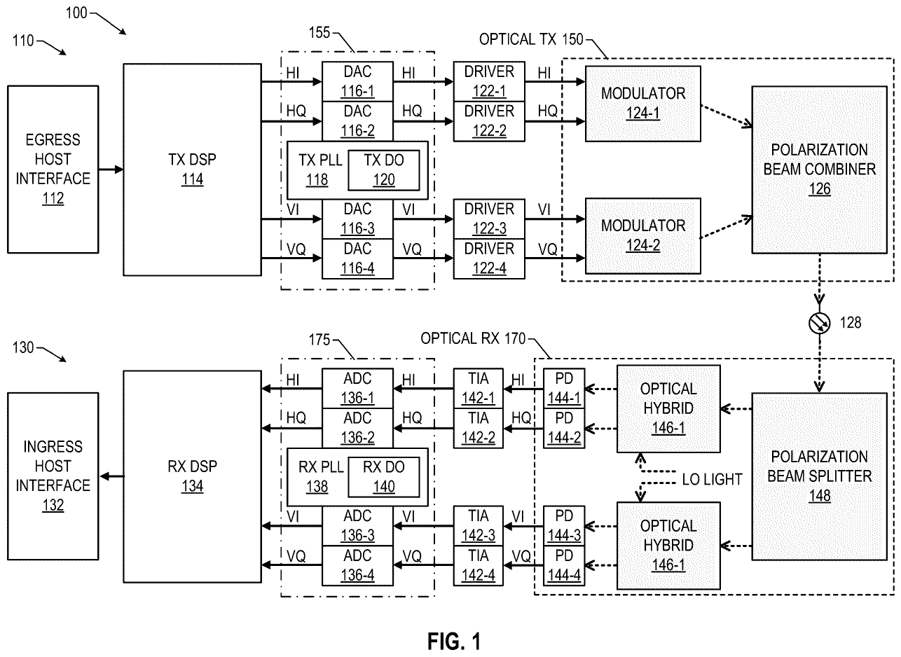

FIG. 1 is a block diagram of an example optical communication system 100 in which one or more tunable DOs with flexible electrical length may be implemented, according to an embodiment. The optical communication system 100 includes a transmitter (TX) module 110 of a first communication device and a receiver (RX) module 130 of a second communication device, coupled to one another by an optical transmission medium 128 such as an optical fiber. In some embodiments, each communication device may include both a TX module and a RX module in order to be able to have two-way communication with other similar communication devices.

As shown in FIG. 1, the TX module 110 may include, from left to right (with arrows indicating direction of signal flow in the TX module 110): an egress host interface 112, a TX digital signal processor (DSP) 114, a plurality of digital-to-analog converters (DACs) 116 (individually labeled as DACs 116-1, 116-2, 116-3, and 116-4), a TX PLL 118, a plurality of optical drivers 122 (individually labeled as optical drivers 122-1, 122-2, 122-3, and 122-4), a plurality of optical modulators 124 (individually labeled as a first optical modulator 124-1 and a second optical modulator 124-2), and a polarization beam combiner (PBC) 126. As further shown in FIG. 1, the RX module 130 may include, from left to right (with arrows indicating direction of signal flow in the RX module 130): an ingress host interface 132, an RX DSP 134, a plurality of analog-to-digital converters (ADCs) 136 (individually labeled as ADCs 136-1, 136-2, 136-3, and 136-4), an RX PLL 138, a plurality of transimpedance amplifiers (TIAs) 142 (individually labeled as TIAs 142-1, 142-2, 142-3, and 142-4), a plurality of photodetectors (PDs) 144 (individually labeled as PDs 144-1, 144-2, 144-3, and 144-4), optical hybrids 146 (individually labeled as a first optical hybrid 146-1 and a second optical hybrid 146-2), and a polarization beam splitter (PBS) 148. The arrows shown in FIG. 1 indicate directions of signal flow. Thus, in the TX module 110, signals flow from left to right, while, in the RX module 130, signals flow from right to left of the drawing. Furthermore, dashed arrows are used to illustrate in FIG. 1 optical signals, while solid arrows are used to illustrate in FIG. 1 electrical signals. Correspondingly, components of the TX module 110 shown within a dashed contour illustrate optical components of the TX module 110 and may be described as being part of an optical TX chip 150, while components of the RX module 130 shown within a dashed contour illustrate optical components of the RX module 130 and may be described as being part of an optical RX chip 170. Thus, the optical TX chip 150 may include the optical modulators 124 and the PBC 126, while the optical RX chip 170 may include the PDs 144, the optical hybrids 146, and the PBS 148. Components of the TX module 110 besides the components included in the optical TX chip 150 are electrical components, and, similarly, components of the RX module 130 besides the components included in the optical RX chip 170 are electrical components.

Turning to the details of the TX module 110, the egress host interface 112 may be configured to accept user payloads and control metadata from an external host device and to deliver a normalized, timing-clean transmit stream to the TX DSP 114. In some embodiments, the egress host interface 112 may implement one or more electrical link protocols (e.g., PCIe, Ethernet MAC/PCS, XAUI/CAUI/400ZR host lanes, JESD-style framed links, or a proprietary SerDes) and may be operable to perform buffering, deskew across multiple lanes, lane aggregation or de-aggregation, elastic store and rate adaptation, protocol termination (e.g., MAC/PCS delineation, block/packet framing detection), header stripping or re-tagging, and payload extraction. In some implementations, the egress host interface 112 may be configured to scramble/descramble payload blocks (e.g., 64b/66b or 256b/257b), verify or append error-checking fields (CRC/FCS), and support optional security primitives (e.g., key-based encryption/authentication) under host control. The egress host interface 112 may further include flow-control mechanisms (e.g., credit-based or pause-frame control), priority queues, and traffic shaping to meet quality-of-service constraints and may implement gearbox functions to translate between host lane rates and the internal sampling rate required by the TX DSP 114. At the boundary with the TX DSP 114, the egress host interface 112 may output a contiguous sequence of payload symbols or fixed-point samples via a well-defined internal bus (e.g., parallel LVDS slices, AXI-Stream, or JESD-style lanes), possibly with accompanying sideband signals (frame/byte-valid, start-of-packet, end-of-packet, lane-good, and time-stamp/sequence identifiers). By normalizing data width, symbol order, and timing, and by enforcing alignment markers across lanes, the egress host interface 112 may present the TX DSP 114 with a deterministic, protocol-agnostic stream suitable for subsequent DSP operations such as forward-error-correction (FEC) encoding, constellation mapping, pulse-shaping, pre-emphasis/equalization, and any required training or pilot insertion.

The TX DSP 114 may be configured to receive the output of the egress host interface 112 (e.g., to receive a protocol-normalized, timing-aligned payload stream) and condition the data for conversion to analog and subsequent electro-optic modulation. The TX DSP 114 may include any suitable circuitry for performing various signal processing tasks on the digital signals received from the egress host interface 112, such as filtering, modulation, and error correction, to optimize transmission quality. For example, the TX DSP 114 may implement impedance matching and signal conditioning to ensure compatibility with downstream driver circuitry (e.g., with the optical drivers 122). In addition, the TX DSP 114 may incorporate equalization techniques such as pre-emphasis or de-emphasis to compensate for frequency-dependent losses in the electrical interconnect path. In some embodiments, the TX DSP 114 may perform frame delineation and payload validation, FEC encoding (e.g., block or convolutional codes with optional interleaving), scrambling, and/or any required encapsulation or overhead insertion (e.g., alignment markers, supervisory bytes, or time-stamp/pilot symbols) to improve link robustness and reduce bit-error rate (BER). In some implementations, the TX DSP 114 may be configured to apply bit-to-symbol mapping to one or more modulation formats (e.g., M-ary QAM, PAM-n), with optional adaptive bit loading or probabilistic shaping, and then conduct digital pulse shaping (e.g., root-raised-cosine or other Nyquist filters) and sample-rate conversion to match downstream converter or modulator rates. The TX DSP 114 may further implement crest-factor reduction and digital predistortion/linearization tailored to the subsequent DACs 116 and optical drivers 122, as well as pre-emphasis and pre-equalization to compensate for known channel or package responses. When the optical communication system 100 is a coherent and/or polarization-multiplexed system, the TX DSP 114 may partition the payload across multiple data channels (e.g., in-phase and quadrature channels, or dual-polarization lanes), insert training or pilot sequences for receiver acquisition, and enforce deterministic latency and phase alignment across channels. Calibration and control functions of the TX DSP 114 may include gain scaling, dither insertion, and numerically controlled oscillator (NCO) mixing for frequency translation. At the transmit boundary with the DACs 116, the TX DSP 114 may output one or more parallel or serial sample streams (e.g., fixed-point I/Q samples) with associated sideband signals (clock, frame/valid, and markers) formatted for the DAC interface, thereby presenting a converter-ready waveform that, when converted and driven into the optical front-end, yields the intended modulated optical signal with prescribed spectral mask, constellation, and error-rate performance. Overall, the TX DSP 114 may serve as a bridge between the high-speed digital data domain and the analog driver circuitry, ensuring that the transmitted signal has sufficient integrity, spectral efficiency, and resilience against noise and channel impairments for reliable conversion into optical signals. The TX DSP 114 may enhance the quality and reliability of the signals before they are converted to analog form by the DACs 116.

In embodiments where the optical communication system 100 is a coherent optical transceiver system, the signal chain downstream of the TX DSP 114 may include four DACs 116-1 through 116-4, with one DAC 116 provided for each of four channels that correspond, for example, to the in-phase (I) and quadrature (Q) components of two orthogonal polarizations (H and V). In the following, such channels may be referred to as HI (H-polarization in-phase), HQ (H-polarization quadrature), VI (V-polarization in-phase), and VQ (V-polarization quadrature). In FIG. 1, signals of the individual channels are labeled by providing the individual channel notation (e.g., HI, HQ, VI, or VQ) above the arrows illustrating the signals. In some embodiments, the TX DSP 114 may deliver, per channel, individual data streams to the respective DACs 116 (e.g., each stream carrying the mapped and pulse-shaped symbols for its assigned channel), possibly together with associated framing and alignment markers to maintain deterministic latency and inter-channel phase coherence. The DACs 116 may include any suitable circuitry for converting the digital signals processed by the TX DSP 114 into analog signals for driving optical components of the TX module 110 using the optical drivers 122. In various embodiments, the DACs 116 may include one or more of binary-weighted DACs, current-steering DACs, charge-redistribution DACs, delta-sigma DACs, and so on. The outputs from the DACs 116 may be provided as differential analog waveforms (e.g., baseband I/Q per polarization) that are phase- and gain-calibrated and are subsequently conditioned by driver and electro-optic stages for modulation onto an optical carrier, thereby preserving the intended constellation, bandwidth, and spectral characteristics established by the TX DSP 114.

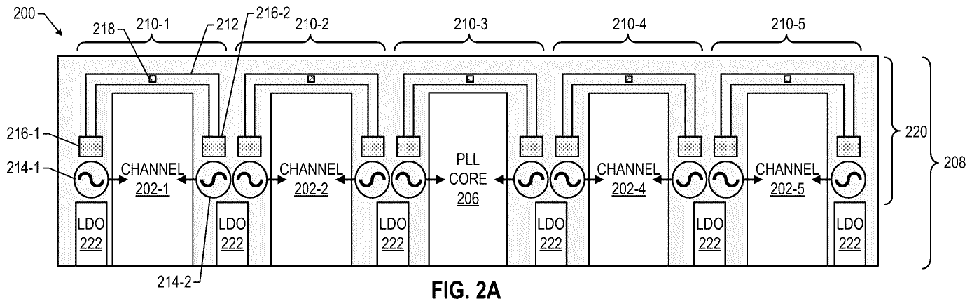

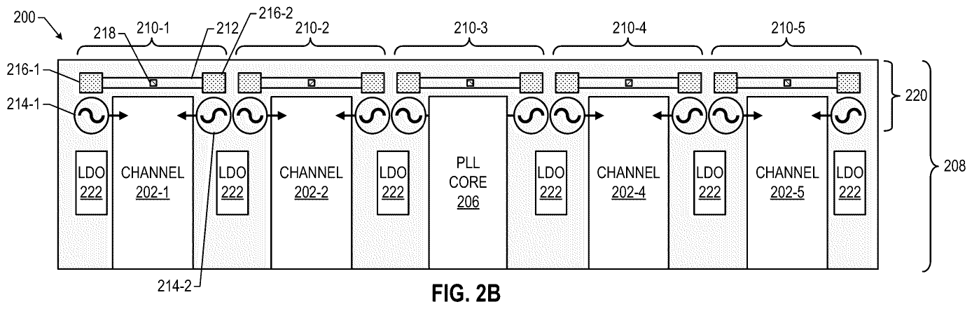

The TX PLL 118 may be configured to generate the sampling and interface clock signals for the DACs 116 to ensure low-jitter conversion and synchronous operation across the four channels. The TX PLL 118 may include a TX DO 120 integrated therein. The TX DO 120 may be a DO with a plurality of DO units connected in series, each DO unit including an inductive matching circuit at each end of the transmission-line segment of the unit, as proposed herein (e.g., as described in greater detail with reference to FIGS. 2A-2B, FIG. 3, and FIGS. 4A-4B).

In embodiments where the optical communication system 100 is a coherent optical transceiver system, the individual analog sample streams generated by the plurality of DACs 116 are each provided to a corresponding optical driver 122, with one optical driver 122 associated with each DAC output channel. The optical drivers 122 may be configured to amplify, level-shift, and otherwise condition the analog HI, HQ, VI, and VQ electrical waveforms to the amplitude, linearity, and bandwidth required for subsequent electro-optic modulation. The optical drivers 122 may include any suitable circuitry for amplifying the analog signals output by the DAC 116 to a level suitable for driving an optical component such as the optical modulator 124. The optical drivers 122 may ensure that the signals have sufficient power to be transmitted over the optical transmission medium 128. The optical drivers 122 may be designed to meet stringent requirements for bandwidth, output swing, linearity, noise performance, and energy efficiency. In some embodiments, the optical drivers 122 may be implemented as differential drivers. The optical drivers 122 may also incorporate impedance matching networks to ensure efficient power transfer and minimize signal reflections at high frequencies. In various implementations, the optical drivers 122 may include pre-emphasis, feed-forward equalization, or other analog equalization techniques to mitigate channel-induced distortion, compensate for parasitic effects, and preserve signal fidelity. Advanced embodiments may also support programmable drive strength or adaptive biasing to balance performance and power consumption across different operating conditions. The optical drivers 122 may function as an interface between the electronic DSP domain and the optical modulation stage, ensuring that high-speed data signals are properly translated into robust modulation of the optical carriers.

Downstream of the optical drivers 122, the conditioned differential analog signals are routed to a pair of optical modulators 124: an H-optical modulator 124-1 and a V-optical modulator 124-2, each configured to modulate an optical carrier using the in-phase (I) and quadrature (Q) components corresponding to one of two orthogonal polarizations. For example, the H-polarization optical modulator 124-1 receives the HI and HQ electrical waveforms from the associated optical drivers 122-1 and 122-2, which in turn are driven by DACs 116-1 and 116-2, while the V-polarization optical modulator 124-2 receives the VI and VQ electrical waveforms from optical drivers 122-3 and 122-4, corresponding to DACs 116-3 and 116-4. The optical modulators 124 may include any suitable components capable of modulating an optical carrier emitted by a laser or other light source. In some embodiments, the optical modulators 124 may include Mach-Zehnder modulators (MZMs), electro-absorption modulators (EAMs), or micro-ring modulators (MRMs), and may impose amplitude and/or phase modulation to create complex optical symbols for each polarization path. Each optical modulator 124 thereby produces a polarization-specific modulated optical field that carries the encoded information for its respective channels.

The polarization beam combiner (PBC) 126 is configured to combine the two independently modulated optical signals generated by the H-optical modulator 124-1 and the V-optical modulator 124-2 into a single dual-polarization optical output suitable for transmission over the optical transmission medium 128. The PBC 126 may be implemented using any suitable polarization-combining device, such as a polarization beam splitter (operated in reverse), a birefringent walk-off crystal, a polarization-maintaining fiber coupler, or an integrated silicon-photonic polarization combiner. In operation, the PBC 126 receives from the H-optical modulator 124-1 the H-polarized optical field (carrying HI and HQ) at one input port and further receives from the V-optical modulator 124-2 the V-polarized optical field (carrying VI and VQ) at another input port. The PBC 126 orients these optical fields into two orthogonal polarization states, e.g., linear horizontal and linear vertical, and combines them into a single spatial mode that propagates along the optical transmission medium 128. Because the two constituent fields occupy orthogonal polarization states, their optical power and complex modulation formats do not interfere with one another during propagation. The resulting combined optical output from the TX module 110 may encode all four channels (HI, HQ, VI, VQ) as a dual-polarization complex-modulated waveform, enabling twice the spectral efficiency relative to a single-polarization system. By delivering this combined output to the optical transmission medium 128, the PBC 126 ensures that both polarizations are co-propagated in a stable and deterministic manner, supporting long-reach coherent transmission with high capacity and high spectral efficiency.

The optical transmission medium 128 may include any suitable optical transmission medium in the form of one or more light-guiding structures, such as optical fibers or waveguides, configured to control and direct the propagation of modulated optical signals from the TX module 110 to the RX module 130. These light-guiding components may take the form of planar waveguides, photonic crystal waveguides, rib waveguides, or conventional optical fibers, all designed to confine light and guide it along predetermined paths with minimal loss, dispersion, or crosstalk. In some embodiments, the optical transmission medium 128 may employ a core material with a higher refractive index surrounded by a cladding material of lower refractive index. This refractive index contrast may confine light within the core via total internal reflection, allowing efficient propagation over distances. Depending on system requirements, the optical transmission medium 128 may support single-mode or multimode propagation and may also incorporate wavelength-division multiplexing (WDM) or dense WDM (DWDM) techniques to increase channel capacity through multiple optical carriers.

Turning to the details of the RX module 130, a polarization beam splitter (PBS) 148 may be configured to receive the dual-polarization optical signal transmitted over the optical transmission medium 128. The PBS 148 separates, or “demultiplexes,” the received optical field into two optical outputs corresponding to orthogonal polarization components, e.g., an H-polarized component and a V-polarized component, thereby substantially preserving the complex modulation carried on each polarization. In operation, the PBS 148 routes the H-polarized optical signal to a first coherent mixing stage and the V-polarized optical signal to a second coherent mixing stage, isolating the tributary information carried on each polarization so that subsequent coherent detection can recover the full in-phase (I) and quadrature (Q) components per polarization.

Downstream of the PBS 148, each polarization component is provided to a respective optical hybrid 146. In some embodiments, an optical hybrid 146-1 is coupled to the H-polarized output of the PBS 148, and an optical hybrid 146-2 is coupled to the V-polarized output of the PBS 148. Each optical hybrid 146 may further receive light from a local-oscillator (LO) source that is split appropriately and, within the hybrid, phase-shifted such that interference occurs at relative LO phases of 0°, 90°, 180°, and 270°. The optical hybrid 146-1 thus produces two optical interference outputs that, when converted by balanced PDs 144-1 and 144-2, yield the HI and HQ electrical signals. Similarly, the optical hybrid 146-2 produces two optical interference outputs that, when converted by balanced PDs 144-3 and 144-4, yield the VI and VQ electrical signals. In this way, the PBS 148 and the pair of optical hybrids 146 may cooperatively recover the complex field (I/Q) for each of the two orthogonal polarizations, providing four electrical outputs (HI, HQ, VI, and VQ) that together capture the full information content of the dual-polarization coherent signal.

Each of the four hybrid outputs (HI, HQ, VI, VQ) may be coupled to a corresponding balanced PD 144 and a transimpedance amplifier (TIA) 142 that convert the optical interference signals into low-noise differential electrical waveforms with appropriate gain and bandwidth. The PDs 144 may include any suitable circuitry for converting the incoming optical signals into electrical signals, such as photocurrent. The PDs 144 may detect the light signals output by the optical hybrids 146 and generate corresponding electrical signals for further processing. Depending on the application requirements, the PDs 144 may comprise a variety of suitable devices, including PIN photodiodes, avalanche photodiodes (APDs), phototransistors, CMOS image sensors, photomultiplier tubes, or quantum PDs. Selection of the PD type may depend on factors such as bandwidth, responsivity, sensitivity, linearity, and noise performance. The PDs 144 may be designed to support the bandwidth of the incoming modulated optical signal received at the RX module 130 while preserving signal fidelity for downstream processing. The TIAs 142 may include any suitable circuitry for amplifying the relatively weak electrical signals generated by the PDs 144 and converting the photocurrent into a voltage signal suitable for further processing. In some embodiments, the TIAs 142 may be designed to optimize the trade-off between gain and bandwidth and may incorporate features such as noise filtering, input impedance matching, and automatic gain control (AGC) to maintain signal integrity across varying input conditions. The RX front-end of the RX module 130 may further include analog conditioning per channel, such as programmable gain control (PGC), analog filtering (e.g., anti-aliasing or baseline-wander correction), DC offset trimming, and optional calibration tone injection to facilitate gain/phase balance and IQ skew compensation.

Following the TIAs 142 and analog conditioning, the HI, HQ, VI, and VQ signals may be sampled by respective high-speed ADCs 136, which operate under a common sampling clock to preserve deterministic latency and inter-channel phase relationships across the four channels. The ADCs 136 may include any suitable circuitry for converting the conditioned analog signals output by the TIAs 142 into digital signals. In various embodiments, the ADCs 136 may include one or more flash ADCs, successive approximation register (SAR) ADCs, delta-sigma ADCs, pipeline ADCs, integrating ADCs, time-interleaved ADCs, etc. Digital signals output by the ADCs 136 may be provided to the RX DSP 134 for digital signal processing, allowing the system to manipulate and analyze the data in a digital format.

The RX PLL 138 may be configured to generate the sampling and interface clock signals for the ADCs 136 to ensure low-jitter conversion and synchronous operation across the four channels. The RX PLL 138 may include an RX DO 140 integrated therein. The RX DO 140 may be a DO with a plurality of DO units connected in series, each DO unit including an inductive matching circuit at each end of the transmission-line segment of the unit, as proposed herein (e.g., as described in greater detail with reference to FIGS. 2A-2B, FIG. 3, and FIGS. 4A-4B).

The digitized HI, HQ, VI, and VQ sample streams may be processed by the RX DSP 134 to perform coherent-receiver signal-processing functions. These may include, without limitation, front-end normalization; IQ imbalance correction on a per-polarization basis; polarization demultiplexing and polarization-mode-dispersion (PMD) compensation using adaptive multiple-input, multiple-output (MIMO) equalizers; chromatic-dispersion (CD) compensation; carrier frequency and phase recovery (e.g., decision-directed or pilot-aided estimation); timing recovery; and adaptive equalization (e.g., feed-forward and decision-feedback equalizers) to mitigate linear channel impairments. The RX DSP 134 may further implement impairment-monitoring and calibration loops, such as local-oscillator phase-noise tracking, gain and offset alignment, and per-lane skew correction, together with frame and packet delineation and forward-error-correction (FEC) decoding as required by the host protocol.

The RX DSP 134 may include any suitable circuitry for operating on the digitized samples from the ADCs 136, including filtering, demodulation, and additional error-correction procedures to optimize reception quality. In some embodiments, the RX DSP 134 may also provide clock-and-data recovery (CDR), retiming, and multiplexing to stabilize and align the recovered data stream prior to delivery to downstream portions of the RX module 130. Advanced embodiments may perform constellation de-mapping for modulation schemes such as NRZ, PAM-4, QAM, or probabilistically shaped formats. By preserving the separation of HI, HQ, VI, and VQ throughout the analog and digital receive chain, the RX module 130 reconstructs the transmitted constellation(s) per polarization and reliably recovers the user payload with the prescribed bit-error-rate performance and spectral efficiency.

The ingress host interface 132 may be configured to receive the recovered payload data streams from the RX DSP 134 and present them to an external host device in a protocol-compliant, timing-stable, and format-normalized manner. In various embodiments, the ingress host interface 132 may implement one or more electrical link protocols (e.g., Ethernet MAC/PCS lanes, PCIe, CAUI/XAUI/400ZR host interfaces, JESD-style framed links, or a proprietary SerDes), and may include buffering, de-skew logic, lane realignment, and elastic-store circuitry to absorb timing variations introduced by the optical channel or DSP processing. The ingress host interface 132 may further support descrambling, FEC de-framing, header reconstruction, re-tagging, and re-insertion of protocol-specific control metadata removed or normalized during transmit or DSP processing.

In some embodiments, the ingress host interface 132 may implement flow-control mechanisms (e.g., credit-based control, pause-frame handling, or priority queuing), and may provide traffic-management functions such as rate adaptation, traffic shaping, and quality-of-service enforcement. The ingress host interface 132 may additionally assemble the recovered data into protocol-defined blocks or packet boundaries, enforce deterministic ordering and timestamp alignment across multiple lanes, and ensure timing compatibility with the host-side clock domains. At the host boundary, the ingress host interface 132 may output a contiguous, protocol-formatted data stream over a well-defined host interface (e.g., high-speed differential SerDes lanes, AXI stream interfaces, or parallel LVDS slices), together with sideband signals indicating data validity, frame boundaries, error status, and link state.

By performing these functions, the ingress host interface 132 effectively bridges the high-speed coherent-DSP domain and the host-protocol domain, delivering correctly aligned, protocol-compliant user data with predictable latency and stable timing to the external host system.

FIG. 1 further illustrates a dashed box indicating optical components of the TX module 110 which may be implemented on a single chip of an optical transmitter or an optical transceiver. Such a chip may be referred to as an optical TX chip 150 in some implementations and may include the PBC 126 and the optical modulators 124. In some embodiments, the optical drivers 122 may also be included in the optical TX chip 150, but, in other embodiments, the optical drivers 122 may be external to the optical TX chip 150. Similarly, FIG. 1 illustrates a dashed box indicating optical components of the RX module 130 which may be implemented on a single chip of an optical receiver or an optical transceiver. Such a chip may be referred to as an optical RX chip 170 in some implementations and may include the PBS 148, the optical hybrids 146, and the PDs 144. In some embodiments, the PDs 144 may be external to the optical RX chip 170.

In some embodiments, the optical communication system 100 may incorporate one or more photonic integrated circuits (PICs). A PIC may be a miniaturized, integrated optical device that combines multiple photonic components, such as optical modulators, PDs, and waveguides, onto a single substrate. For example, a PIC may include components of the optical TX chip 150, or the optical TX chip 150 may include one or more PICs. In another example, a PIC may include components of the optical RX chip 170, or the optical RX chip 170 may include one or more PICs. Additionally, a PIC may integrate one or more waveguides, which may include any of the waveguide structures described with reference to the optical transmission medium 128. By integrating multiple photonic functions on a single substrate, the PIC can reduce footprint, improve signal integrity, and enable scalable, high-performance optical communication.

FIG. 1 also illustrates a dash-dotted box indicating electrical components of the TX module 110 which may be implemented on a single chip of an optical transmitter or an optical transceiver along with a DO as proposed herein. Such a chip may be referred to as a TX DO chip 155 in some implementations and may include the TX PLL 118 with the TX DO 120 and may further include the DACs 116. Similarly, FIG. 1 illustrates a dash-dotted box indicating electrical components of the RX module 130 which may be implemented on a single chip of an optical receiver or an optical transceiver along with a DO as proposed herein. Such a chip may be referred to as an RX DO chip 175 in some implementations and may include the RX PLL 138 with the RX DO 140 and may further include the ADCs 136. In some embodiments, the TIAs 142 may also be included in the RX DO chip 175, but, in other embodiments, the TIAs 142 may be external to the RX DO chip 175.

FIG. 1 depicts several components of the optical communication system 100; however, depending on the implementation, one or more of these components may be omitted, replicated, or otherwise modified to suit the particular application. In certain embodiments, some or all of the illustrated components may be mounted on one or more motherboards or other suitable support structures. In other embodiments, some or all of the components may be integrated into a single system-on-chip (SoC) die. Furthermore, in some implementations, the optical communication system 100 may exclude one or more of the components shown in FIG. 1 and instead employ interface circuitry configured to couple to such components externally. For example, the optical communication system 100 may not include the optical TX chip 150 or the optical RX chip 170, but may include interface circuitry (e.g., a connector) to which the optical TX chip 150 or the optical RX chip 170 may be coupled.

Other components may be present in the optical communication system 100 besides those shown in FIG. 1. Examples of such other components include a SerDes, digital predistortion (DPD) circuitry, power management integrated circuitry (PMIC), optical coupling interfaces, optical amplifiers, or various passive components, described below.

A SerDes of the optical communication system 100 may be configured to convert parallel data streams into serial data streams for transmission over high-speed interfaces, or to perform the reverse operation on received data. By converting between parallel and serial formats, the SerDes may facilitate efficient high-bandwidth data transfer between electronic processing units and the optical communication system 100. The SerDes may further include features such as CDR, word alignment, and de-skewing to maintain signal integrity across the interface. In some embodiments, the SerDes may be integrated with the TX DSP 114 and/or RX DSP 134, providing a tightly coupled interface between digital processing and optical transmission.

DPD circuitry of the optical communication system 100 may be configured to apply pre-compensation to electrical signals prior to their conversion into optical signals by the optical drivers 122 and optical modulators 124. By intentionally shaping or modifying the input signals, the DPD circuitry may be able to counteract known nonlinearities, distortions, and frequency-dependent impairments present in the optical driver, modulator, or transmission path. This may result in improved linearity, reduced signal distortion, and enhanced overall fidelity of the modulated optical signal. In various embodiments, the DPD circuitry may operate in the digital domain within the TX DSP 114 or as a separate processing block. The DPD algorithms may be adaptive, continuously adjusting to changes in system characteristics such as temperature, aging, or component variability, thereby maintaining optimal signal quality over time. By compensating for distortions before transmission, the DPD circuitry can improve the BER, increase achievable data rates, and support higher-order modulation formats in the optical communication system 100.

PMIC of the optical communication system 100 may comprise any suitable controller, such as a microcontroller, configured to manage and regulate the operation of various components within the optical communication system 100. In certain embodiments, the PMIC may provide feedback-controlled biasing for the optical modulators 124, helping to achieve stable performance across temperature variations and over the device lifetime. To achieve this, the PMIC may include bias circuitry capable of applying a controlled DC voltage or current to establish the optimal operating point of the optical source and/or modulator. The PMIC may also integrate monitoring PDs and control loops to dynamically adjust the bias based on real-time output measurements. In some embodiments, the PMIC may be located within the TX module 110, the RX module 130, or both.

An optical coupling interface may be present between the output of the TX module 110 (e.g., the output of the PBC 126) and the optical transmission medium 128 to achieve efficient light transfer between the two. Such an optical coupling interface may include a variety of coupling mechanisms, such as fiber couplers (e.g., fused or tapered fiber couplers), waveguide couplers, grating couplers, edge couplers, lens-based couplers, microlens arrays, prism couplers, fiber array couplers, or ball lens couplers. These components may be designed to ensure minimal insertion loss and efficient optical alignment between the TX module 110 and the optical transmission medium 128. A similar optical coupling interface may be present between the optical transmission medium 128 and the input to the RX module 130 (e.g., the input to the PBS 148).

One or more optical amplifiers of the optical communication system 100 may be configured to directly amplify optical signals without first converting them to electrical signals. Such amplification can be used to boost optical power within a waveguide or fiber, for example in the optical transmission medium 128, helping to maintain signal strength and quality over long distances or through lossy components. In various embodiments, optical amplifiers of the optical communication system 100 may include semiconductor optical amplifiers (SOAs), erbium-doped fiber amplifiers (EDFAs), Raman amplifiers, or hybrid/integrated amplifiers combining SOAs with other photonic elements. One or more optical amplifiers may be incorporated into any or all of the TX module 110, RX module 130, and optical transmission sub-system between the TX module 110 and the RX module 130.

Various passive optical components may be included in the optical communication system 100. Such passive optical components may include elements such as multiplexers, demultiplexers, periodic optical filters, splitters, or ring resonators. These components may be configured to manage optical signal routing, separate or combine wavelengths, suppress undesired spectral components, and generally facilitate precise control over optical paths within the optical communication system 100.

In certain embodiments, the optical communication system 100 may function as an optical communication interconnect (OCI) system, providing high-speed, low-latency, and energy-efficient data transfer between nodes (e.g., various electronic processing units) via an optical transmission medium. Such processing units may include, for example, CPUs, GPUs, or FPGAs. In some applications, the optical communication system 100 may be employed for chip-to-chip or chiplet-level interconnects, thereby enabling dense optical I/O between integrated circuit dies in advanced multi-die packaging. In other scenarios, the optical communication system 100 may be used for rack-scale or board-level interconnects, such as replacing traditional copper links in AI clusters and data centers with optical fibers in order to reduce power consumption and improve bandwidth scalability. In yet other applications, the optical communication system 100 may be configured for co-packaged optics (CPO), where optical transmitters and receivers are integrated in close proximity to switching units (e.g., ASICs) in data center switches. This arrangement may help overcome limitations of electrical I/O, thereby supporting higher aggregate bandwidths while reducing energy per bit.

FIGS. 2A-2B illustrate different examples of an arrangement 200 of channels and a PLL with an integrated tunable DO with flexible electrical length, according to various embodiments.

As shown in FIG. 2A, the arrangement 200 may include a plurality of channels 202, e.g., four channels 202 (individually labeled as channels 202-1, 202-2, 202-3, and 202-4). If the arrangement 200 is part of a coherent optical system, the four channels 202 may be channels HI, HQ, VI, or VQ, described above. Each channel 202 may include components configured to process signals for the corresponding channel. If the arrangement 200 is part of a transmitter, e.g., the TX module 110, then different ones of the channels 202 may include respective DACs, e.g., respective ones of the DACs 116. If the arrangement 200 is part of a receiver, e.g., the RX module 130, then different ones of the channels 202 may include respective ADCs, e.g., respective ones of the ADCs 136. As further shown in FIG. 2A, the arrangement 200 may include a PLL 208 that may include a DO 220 integrated therein. If the arrangement 200 is part of a transmitter, e.g., the TX module 110, then the PLL 208 may be an example of the TX PLL 118 and the DO 220 may be an example of the TX DO 120. If the arrangement 200 is part of a receiver, e.g., the RX module 130, then the PLL 208 may be an example of the RX PLL 138 and the DO 220 may be an example of the RX DO 140.

The foregoing description illustrates that the arrangement 200 may be an example, or a part, of the TX DO chip 155 or of the RX DO chip 175. However, even though parallels are drawn herein between components of the arrangement 200 and portions of the optical communication system 100, described above, in other embodiments, the arrangement 200 may be part of an optical communication system other than the optical communication system 100. In some embodiments, the arrangement 200 may be part of any optical communication system where tunable DOs with flexible electrical length may be used, e.g., part of a CPO or an OCI system. In some embodiments, the arrangement 200 may be part of a communication system other than an optical communication system. For example, the arrangement 200 may be part of any electrical communication system where tunable DOs with flexible electrical length may be used, e.g., part of a PCIe system, part of an Ethernet backplane system, or part of a SerDes system. In some embodiments, the arrangement 200 may be part of an RF or microwave communication system, wireless technologies such as 5G and satellite communication, radar systems, and test and measurement equipment.

As shown in FIG. 2A, the PLL 208 may include a PLL core 206, while the DO 220 may include a plurality of DO units 210 (individually labeled as DO units 210-1, 210-2, 210-3, 210-4, and 210-5). To avoid overcrowding the drawing, individual subcomponents are explicitly annotated for DO unit 210-1 only. In one embodiment, each DO unit 210 includes a transmission-line segment 212 having a first end and an opposite second end (with a portion therebetween referred to as a “middle portion”), a first oscillator 214-1 coupled (e.g., directly electrically connected) to the first end, and a second oscillator 214-2 coupled to the second end. Each DO unit 210 further includes a first inductive matching circuit 216-1 coupled between the first oscillator 214-1 and the transmission-line segment 212, and a second inductive matching circuit 216-2 coupled between the second oscillator 214-2 and the transmission-line segment 212. In some embodiments, the first inductive matching circuit 216-1 is coupled between the first oscillator 214-1 and the middle portion of the transmission-line segment 212, while the second inductive matching circuit 216-2 is coupled between the second oscillator 214-2 and the middle portion, thereby presenting controlled inductive reactance at both terminations of the line segment to tailor the unit's resonance and inter-unit coupling. The plurality of DO units 210 may be connected in a daisy-chained configuration (e.g., connected in series) so that energy injected by each end oscillator is shared along adjacent DO units 210 and the aggregate structure forms a multi-segment standing-wave resonator suitable for high-frequency clock generation and distribution.

In some embodiments, any of the oscillators 214 may be implemented as VCOs, in which case the DO 220 operates as a DVCO. In other embodiments, any of the oscillators 214 may be implemented as CCOs, DCOs, ILOs, or oscillators of any other topologies and types described above. In some embodiments, an oscillator 214 may include a transconductance (Gₘ) stage configured to supply negative resistance sufficient to offset resonator losses and sustain oscillation, together with tuning elements to set the oscillation frequency. In various embodiments, the tuning elements of the oscillators 214 may include integrated varactors (e.g., accumulation-mode metal-oxide-semiconductor (MOS) or PN-junction varactors) to adjust effective capacitance, digitally switchable capacitor arrays to provide coarse tuning steps, and, in certain embodiments, switchable or variable inductors to adjust inductive loading at the line terminations of the transmission-line segment 212.

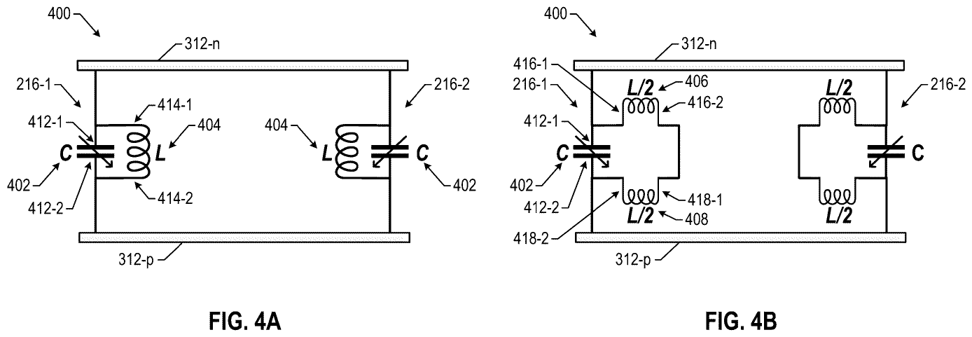

The inductive matching circuits 216-1 and 216-2 may each comprise one or more inductors and one or more capacitors arranged to realize a desired impedance transformation and to introduce a controlled phase rotation at the operating frequency. By appropriate selection or tuning of the elements of the inductive matching circuits 216-1 and 216-2, the effective inductance (or net reactive impedance) presented to the transmission-line segment 212 may be controlled. In some implementations, the inductive matching circuits 216 may be realized as spiral or transmission-line inductors with parallel/series capacitors, optionally employing digitally selectable capacitor banks or switchable inductive sections to enable both coarse and fine phase/electrical-length adjustment, with some examples shown in FIGS. 4A-4B. By tuning the inductance or effective reactance of the inductive matching circuits 216-1 and 216-2, the phase at the ends of the transmission-line segment 212 may be adjusted so that the effective electrical length of the transmission-line segment 212 is shortened relative to its physical length, thereby enabling resonance at higher frequencies than would otherwise be permitted. For example, by tuning the inductance or effective reactance of the end networks provided by the inductive matching circuits 216-1 and 216-2, the reflection phase at the line terminations may be intentionally altered so that, from the standpoint of the oscillation condition, the transmission-line segment 212 behaves as though it were electrically shorter than its physical length. This effect can be visualized on a Smith chart by considering the impedance seen looking into the transmission line from one end: for a given physical line length l, the input impedance Zᵢₙ is related to the termination impedance Z_{L} by a rotation around the Smith chart along a constant-/Γ/ circle, where the angular distance of the rotation corresponds to the electrical length βl (with β being the phase constant). In a conventional DO unit without the inductive matching circuits 216-1 and 216-2, the termination presented by the oscillator circuitry (and any fixed parasitics) sets a particular load point on the Smith chart, and the physical line length produces a fixed amount of rotation that determines where the input impedance lands. In such a case, the oscillation frequency must then satisfy the resonance condition dictated by that fixed round-trip phase. In contrast, the disclosed inductive matching circuitry moves the effective termination point Z_{L} on the Smith chart (e.g., by adding a controllable inductive susceptance and/or an impedance transformation), thereby changing the required Smith-chart rotation needed for the input impedance to reach the same target locus associated with the oscillation condition (e.g., a desired resistive point or a point satisfying the negative-resistance startup criterion of the end oscillators). Stated differently, the transmission-line segment 212 may still contribute a physical propagation delay, but the tunable reactive networks at the ends may contribute an additional, controllable phase shift in the reflection coefficient. On the Smith chart, this may appear as a deliberate repositioning of the termination so that a smaller electrical rotation (i.e., a smaller effective βl_{eff}) may achieve the same net phase condition that previously required the full βl. As a result, for a fixed physical length l, the resonance (round-trip phase) condition can be satisfied at a higher frequency because the end networks provide phase compensation that reduces the effective electrical length of the transmission-line segment 212 (i.e., l_{eff}<l) relative to its physical length. This engineered phase compensation may restore the resonance condition at a higher oscillation frequency than would otherwise be permitted by the unmodified line, thereby decoupling frequency selection from the physical length of the line and enabling scalable integration, improved layout flexibility, and high-speed clock distribution without sacrificing frequency performance.

The transmission-line segment 212 may be realized using any suitable on-chip or package-level architecture, including coplanar waveguide with ground (CPWG), microstrip, stripline, or differential CPWG, with geometry, ground referencing, and dielectric stack selected to achieve a target characteristic impedance (e.g., 50 Ω to 100 Ω differential) and low loss. In certain embodiments, the transmission-line segment 212 may be a high-quality factor (Q) line, e.g., may be a transmission line having relatively low energy losses (e.g., conductor, dielectric, and radiation losses) to improve phase noise, sustain oscillations with minimal damping over time, and maintain a sharp resonance, which in turn may enhance frequency stability and injection-locking behavior. In some implementations, the transmission-line segment 212 may be configured as a half-wavelength (λ/2) resonator at the nominal operating frequency. Accordingly, the physical length of the transmission-line segment 212 may be selected such that the fundamental standing-wave pattern presents appropriate boundary conditions at the terminations given the impedance presented by the oscillators 214 and the inductive matching circuits 216. In certain embodiments, a midpoint element 218 may be disposed substantially at the midpoint of the transmission-line segment 212 to set injection-locking strength within the DO 220 (e.g., establishing a ratio between power transmitted to adjacent DO units 210 and power reflected back toward the local DO unit 210), to control loop Q, and to stabilize the amplitude distribution along the standing-wave structure. In some embodiments, the midpoint element 218 may include a resistor, e.g., a variable resistor. In some embodiments, the midpoint element 218 may be implemented using any suitable combination of resistors or transistors configured as pass or transmission gates, or may be implemented as any other form of circuitry configured to function as a passive resistive element. In some embodiments, the midpoint element 218 may be implemented as a shunt element to ground (or to a virtual ground in differential implementations) and may be selected to balance locking margin, start-up robustness, and phase-noise performance across process, voltage, and temperature variations.

As further shown in FIG. 2A, in some embodiments, a plurality of low-dropout regulators (LDOs) 222 may be included in the arrangement 200. The LDOs 222 may be configured to provide clean, low-noise, and tightly regulated supply voltages to the oscillators 214, the inductive matching circuits 216, and other sensitive analog portions of the DO 220. The DO 220 may rely on stable biasing conditions to maintain low phase noise, consistent injection-locking behavior, and reliable frequency tuning, in which case the LDOs 222 may be designed to suppress supply ripple, mitigate substrate-borne noise, and isolate the DO units 210 from digital switching transients originating elsewhere in the integrated circuit (IC) or module. In some embodiments, the LDOs 222 may be configured to reduce or minimize effects of voltage variations caused by adjacent digital logic, mixed-signal circuitry, or external power-delivery networks on the oscillation amplitude, tuning range, or phase stability of the DO 220.

In various embodiments, the LDOs 222 may be implemented as low-dropout linear regulators using P-type transistors (e.g., P-type metal-oxide-semiconductor (PMOS) transistors) or N-type transistors (e.g., N-type metal-oxide-semiconductor (NMOS) transistors), with internal or external compensation networks selected to ensure fast transient response and robust loop stability across process, voltage, and temperature variations. In some embodiments, the LDOs 222 may further include programmable reference voltages, digitally adjustable output levels, soft-start circuits, current limiting, and thermal protection. In some embodiments, the LDOs 222 may be implemented as NMOS-only biasing regulators to reduce headroom requirements and to enable the DO 220 to operate at bias levels near VDD/2, thereby simplifying power distribution and improving linearity of the transconductance stages within the oscillators 214. In some embodiments, the LDOs 222 may be configured so that they may be bypassed, in which case the DO 220 may be configured to be connected directly to an external source of voltage supply. Additional embodiments may employ distributed local decoupling capacitors, on-chip bypassing networks, and dedicated analog supply rails to further reduce high-frequency noise coupling into the DO units 210.

In some embodiments, the LDOs 222 may be physically positioned in close proximity to the DO units 210, e.g., placed between adjacent DO units 210 or flanking each DO unit 210 within reserved layout regions, to minimize power-routing parasitics and to ensure that each DO unit 210 receives a stable, low-impedance supply node. In some embodiments, the LDOs 222 may be positioned in the “gaps” or channel-spacing regions between the channels 202, as shown in FIGS. 2A-2B, thereby taking advantage of natural whitespace in the layout while preserving symmetry of the DO structure. In other embodiments, the LDOs 222 may be grouped near the PLL core 206 (not shown in FIGS. 2A-2B) or distributed in any other suitable manner along the length of the DO 220 to ensure uniform supply regulation across the entire chain of DO units 210. Placement may be further optimized to reduce coupling between digital and analog domains, avoid magnetic interference with the inductive matching circuits 216, and maintain consistent thermal environments for the oscillators 214. By delivering stable, low-noise power at strategic locations throughout the arrangement 200, the LDOs 222 support improved frequency stability, lower phase noise, and robust injection-locking performance of the DO architecture.

The arrangements 200 shown in FIGS. 2A and 2B are generally similar in overall architecture, differing primarily in how the transmission-line segments 212 are physically routed within the DO units 210. In particular, FIG. 2A illustrates an embodiment in which the transmission-line segment 212 of each DO unit 210 at least partially wraps around the corresponding one of the channels 202 or the PLL core 206. For example, in some embodiments, the transmission-line segment 212 includes a portion disposed above the corresponding channel 202 or PLL core 206 and additional portions extending along the left and right sides, thereby forming a partially or fully encircling path around the underlying circuitry. This wrap-around configuration may reduce the lateral footprint of the DO units 210, permitting transmission-line segments 212 of the required physical length to be accommodated within a more compact area. Such routing of the transmission-line segments 212 may facilitate tighter integration of the DO 220 within a dense mixed-signal environment while helping maintain symmetry across the DO units 210 and supporting consistent coupling conditions.

By contrast, FIG. 2B illustrates an embodiment in which the transmission-line segment 212 of each DO unit 210 does not wrap around the corresponding channel 202 or PLL core 206. In this arrangement, the transmission-line segment 212 may include only a portion located above the corresponding channel or PLL core, as shown in FIG. 2B, or only a portion positioned below the corresponding element (not shown), without lateral segments extending along the sides as in FIG. 2A. This non-wrapping layout may simplify routing, reduce design complexity, and provide improved isolation between adjacent transmission-line segments 212 or between transmission-line segments 212 and adjacent functional blocks (e.g., digital logic regions or switching circuits). Additionally, such an arrangement may offer advantages in electromagnetic compatibility, reduce unwanted parasitic coupling, ease compliance with metal-density or routing-blockage rules, and improve manufacturability by avoiding routing congestion around tall analog or mixed-signal structures. In some implementations, the linear or single-sided placement of transmission-line segments may also enhance thermal uniformity and simplify placement of nearby LDOs 222, decoupling capacitors, or bias-distribution networks that support the DO units 210.

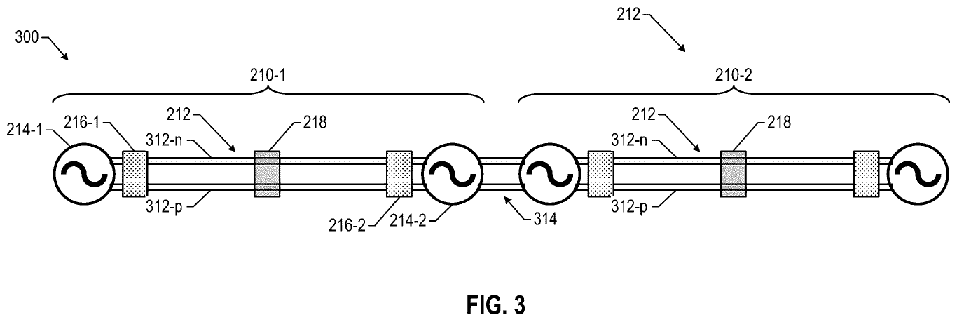

Further details of the DO units 210 are provided with reference to FIG. 3 and FIGS. 4A-4B. In particular, FIG. 3 illustrates an example of a tunable DO 300 with two DO units 310, according to an embodiment, while FIGS. 4A-4B illustrate different examples of inductive matching circuits 216 within a DO unit 400, according to various embodiments. The DO 300 may be an example of the DO 220 (or a portion thereof), and the DO units 310 or DO units 400 may be examples of the DO units 210. Taken together, these figures demonstrate how transmission-line segments 212, oscillators 214, and inductive matching circuits 216 may be combined to realize a tunable, distributed, multi-segment resonant structure suitable for high-frequency clock generation and distribution.

As illustrated in FIG. 3, in some embodiments the transmission-line segments 212 may be implemented as differential transmission lines, each having a negative signal branch 312-n and a positive signal branch 312-p. In such embodiments, an inductive matching circuit 216 may be coupled (e.g., directly electrically connected) between the differential branches 312-n and 312-p at a location proximate to a corresponding oscillator 214 at a given end of the transmission-line segment 212. The differential implementation may provide improved common-mode noise rejection, enhanced immunity to substrate-borne interference, and greater symmetry in the field distribution of the resonant structure. FIG. 3 further illustrates that adjacent oscillators 214 belonging to two consecutive DO units 210 may be coupled via a differential connection 314, which may be a direct electrical connection between corresponding differential nodes. For example, the differential connection 314 may couple the second oscillator 214-2 of the DO unit 210-1 with the first oscillator 214-1 of the DO unit 210-2, and so on for other adjacent DO units 210. This differential inter-unit coupling may enable controlled injection locking, facilitate propagation of the resonant waveform along the chain of DO units 210, and help maintain deterministic phase relationships throughout the DO.

Continuing with the differential implementation, FIGS. 4A and 4B each illustrate an example of a DO unit 400 that may correspond to the DO unit 210 shown in FIG. 3, but with the oscillators 214 and the midpoint element 218 omitted to avoid cluttering the drawings.

FIG. 4A demonstrates that each of the inductive matching circuits 216-1 and 216-2 may include a capacitor 402 (having a capacitance C) coupled between the negative signal branch 312-n and the positive signal branch 312-p, as well as an inductor 404 (having an inductance L) coupled in parallel with the capacitor 402. Thus, for each of the inductive matching circuits 216-1 and 216-2, a first terminal 414-1 of the inductor 404 may be coupled with a first terminal 412-1 of the capacitor 402, and a second terminal 414-2 of the inductor 404 may be coupled with a second terminal 412-2 of the capacitor 402, forming a parallel LC network across the differential transmission-line branches 312-n and 312-p. In some embodiments, the capacitor 402 may be implemented as a variable (tunable) capacitor, such as a digitally switchable capacitor array or a MOS varactor. In some embodiments, the inductor 404 may be implemented as a variable (tunable) inductor or may include multiple selectable inductive segments. Adjusting the values of C and/or L may allow fine control over the total inductive reactance (or net impedance) presented to the differential transmission-line segment 212 at a given location. Such tuning may enable precise phase adjustment at the ends of the transmission-line segment 212, allowing tuning of the effective electrical length of the transmission-line segment 212, and facilitate operation of the DO at a target resonance frequency even when the physical length of the transmission-line segment would otherwise impose a lower natural resonant frequency.

FIG. 4B demonstrates that, in some embodiments, each of the inductive matching circuits 216-1 and 216-2 may include the capacitor 402 (having capacitance C) as shown in FIG. 4A, together with a pair of inductors 406 and 408 arranged in series. In the illustrated embodiment, each of inductors 406 and 408 may have an inductance value of approximately L/2, such that the two inductors 406 and 408, when connected in series, present a total inductance of approximately L. As shown, a first terminal 416-1 of the first inductor 406 may be coupled with the first terminal 412-1 of the capacitor 402, a second terminal 416-2 of the first inductor 406 may be coupled with a first terminal 418-1 of the second inductor 408, and a second terminal 418-2 of the second inductor 408 may be coupled with the second terminal 412-2 of the capacitor 402. In this manner, the two inductors 406 and 408 are connected in series with one another, and the resulting series-inductor combination is connected in parallel with the capacitor 402, forming a parallel LC network across the differential branches 312-n and 312-p of the transmission-line segment 212.

The topology as shown in FIG. 4B may provide several advantages relative to the single-inductor implementation of FIG. 4A. For example, implementing the total inductance as two series inductors 406 and 408 may facilitate finer tuning granularity, as the inductors 406 and 408 may each be individually selectable, adjustable, or bypassable (e.g., through digitally controlled switches) to realize multiple discrete inductance values or to calibrate the net inductive reactance at the line termination. In some embodiments, one of the inductors 406 or 408 may be a fixed inductor while the other may be a variable inductor (e.g., realized using a magnetic-coupling-based variable inductor structure or a switched-segment inductor), thereby enabling both coarse and fine inductance tuning. Such a configuration may allow the inductive matching circuit 216 to shift the impedance locus on a Smith chart in a controlled manner, enabling precise electrical-length reduction of the transmission-line segment 212 and facilitating resonance of the DO at frequencies higher than those determined solely by the physical line length.

The topology of FIG. 4B may also offer layout benefits relative to the embodiment shown in FIG. 4A, such as the ability to distribute the metal area required for the inductors of the inductive matching circuits 216 over a larger region or to place the inductors symmetrically with respect to the differential branches, thereby reducing parasitic coupling, improving Q-factor, and minimizing mutual inductance between adjacent DO units. In addition, splitting a total inductance into multiple series elements may simplify the use of thick-metal layers or multi-turn inductor geometries while maintaining a compact footprint and alignment with adjacent transmission-line routing. Overall, the series-inductor configuration of FIG. 4B may provide a flexible and tunable termination network that can support an enhanced operating-frequency range, improved phase-control capability, and better manufacturability within the DO architecture.

On the other hand, the inductive matching topology illustrated in FIG. 4A may also offer advantages over the configuration of FIG. 4B. Because FIG. 4A employs a single inductor in parallel with a capacitor, the inductive matching circuits 216 introduce fewer series resistances and parasitic elements, which may lead to higher effective Q, lower loss, and cleaner high-frequency behavior. Furthermore, the simplified LC structure as shown in FIG. 4A may help reduce layout complexity, minimize routing parasitic effects, and occupy a smaller physical footprint, compared to the implementation of FIG. 4B, which can be beneficial in dense mixed-signal environments. In addition, tuning and calibration may be easier to implement in the FIG. 4A topology, as only a single inductive branch of an inductive matching circuit 216 is to be controlled rather than multiple series elements whose tolerances and variability may interact. The reduced number of components of the embodiment of FIG. 4A may further decrease sensitivity to process variations, limit the formation of unintended resonances, and help maintain more predictable impedance characteristics across operating conditions. Overall, the FIG. 4A implementation may provide a compact, low-loss, and more easily tunable inductive matching structure that can support improved phase accuracy, better injection-locking performance, and more stable high-frequency operation within the DO architecture.

In various deployment scenarios, system designers may select the embodiment of FIG. 4A or FIG. 4B based on differing architectural priorities, performance targets, and layout constraints of the DO implementation. For instance, applications that demand maximum Q-factor, lowest loss, highest frequency headroom, and predictable high-frequency behavior may prefer the FIG. 4A topology because its single-inductor structure may minimize parasitic resistances and simplify tuning, thereby supporting cleaner resonance characteristics and more stable injection-locking across a wide range of operating conditions. FIG. 4A may also be advantageous in compact or noise-sensitive layouts in which minimizing area, reducing parasitic coupling, and maintaining a straightforward component arrangement are critical to overall DO performance. Conversely, deployment scenarios that require greater tuning granularity, flexible inductance scaling, or finer control of the impedance profile at the transmission-line termination may prefer the FIG. 4B embodiment. The use of two series inductors in FIG. 4B may allow designers to implement switched-segment inductors or hybrid configurations (e.g., one fixed and one variable inductor), enabling more nuanced coarse-and-fine inductance adjustment or calibration after packaging or during run-time adaptation. FIG. 4B may also be desirable when layout constraints favor distributing the inductance across multiple smaller inductors, e.g., in large-area DOs in which spreading magnetic fields or minimizing mutual coupling to adjacent lines is beneficial. Thus, depending on whether low-loss simplicity or high-precision tunability and layout flexibility is the overriding design objective, system architects may choose between the FIG. 4A or FIG. 4B implementations to optimize DO performance for the particular deployment environment.

The following paragraphs provide examples of various ones of the embodiments disclosed herein.

Example 1 provides an electronic component that includes a transmission line having a first end, a second end, and a middle portion between the first end and the second end; a first oscillator coupled (e.g., directly electrically connected) with the first end; a second oscillator coupled (e.g., directly electrically connected) with the second end; a first circuit coupled between (e.g., directly electrically connected with each of) the first oscillator and the middle portion, e.g., coupled with the first oscillator and the first end; and a second circuit coupled between (e.g., directly electrically connected with each of) the second oscillator and the middle portion, e.g., coupled with the second oscillator and the second end, in which: the first circuit includes a first capacitor having a first terminal coupled (e.g., directly electrically connected) with a negative signal branch of the transmission line and having a second terminal coupled (e.g., directly electrically connected) with a positive signal branch of the transmission line, and further includes one or more first inductors coupled (e.g., directly electrically connected) with the first capacitor, and the second circuit includes a second capacitor having a first terminal coupled (e.g., directly electrically connected) with the negative signal branch of the transmission line and having a second terminal coupled (e.g., directly electrically connected) with the positive signal branch of the transmission line, and further includes one or more second inductors coupled (e.g., directly electrically connected) with the second capacitor.

Example 2 provides the electronic component of example 1, in which: the one or more first inductors includes a first inductor having a first terminal coupled (e.g., directly electrically connected) with the first terminal of the first capacitor and having a second terminal coupled (e.g., directly electrically connected) with the second terminal of the first capacitor, and the one or more second inductors includes a second inductor having a first terminal coupled (e.g., directly electrically connected) with the first terminal of the second capacitor and having a second terminal coupled (e.g., directly electrically connected) with the second terminal of the second capacitor.

Example 3 provides the electronic component of example 1, in which: the one or more first inductors include a first inductor and an additional first inductor, a first terminal of the first inductor is coupled (e.g., directly electrically connected) with the first terminal of the first capacitor, a second terminal of the first inductor is coupled (e.g., directly electrically connected) with a first terminal of the additional first inductor, a second terminal of the additional first inductor is coupled (e.g., directly electrically connected) with the second terminal of the first capacitor, the one or more second inductors include a second inductor and an additional second inductor, a first terminal of the second inductor is coupled (e.g., directly electrically connected) with the first terminal of the second capacitor, a second terminal of the second inductor is coupled (e.g., directly electrically connected) with a first terminal of the additional second inductor, and a second terminal of the additional second inductor is coupled (e.g., directly electrically connected) with the second terminal of the second capacitor.

Example 4 provides the electronic component of any one of the preceding examples, in which the first capacitor is a first variable capacitor and the second capacitor is a second variable capacitor.

Example 5 provides the electronic component of any one of the preceding examples, in which: the transmission line, the first oscillator, the second oscillator, the first circuit, and the second circuit are portions of a first oscillator unit, the electronic component further includes a second oscillator unit, the second oscillator unit includes an additional transmission line, an additional first oscillator, an additional second oscillator, an additional first circuit, and an additional second circuit, the additional transmission line has a first end, a second end, and a middle portion between the first end and the second end, the additional first oscillator is coupled (e.g., directly electrically connected) with the first end of the additional transmission line, the additional second oscillator is coupled (e.g., directly electrically connected) with the second end of the additional transmission line, the additional first circuit is coupled between (e.g., directly electrically connected with each of) the additional first oscillator and the middle portion of the additional transmission line, and the additional second circuit is coupled between (e.g., directly electrically connected with each of) the additional second oscillator and the middle portion of the additional transmission line.

Example 6 provides the electronic component of example 5, in which: the first oscillator of the second oscillator unit is coupled with the second oscillator of the first oscillator unit.

Example 7 provides the electronic component of examples 5 or 6, in which: the additional first circuit includes an additional first capacitor having a first terminal coupled (e.g., directly electrically connected) with a negative signal branch of the additional transmission line and having a second terminal coupled (e.g., directly electrically connected) with a positive signal branch of the additional transmission line, and further includes one or more additional first inductors coupled (e.g., directly electrically connected) with the additional first capacitor, and the additional second circuit includes an additional second capacitor having a first terminal coupled (e.g., directly electrically connected) with the negative signal branch of the additional transmission line and having a second terminal coupled (e.g., directly electrically connected) with the positive signal branch of the additional transmission line, and further includes one or more additional second inductors coupled (e.g., directly electrically connected) with the additional second capacitor.

Example 8 provides the electronic component of example 7, in which: the one or more additional first inductors include a first inductor having a first terminal coupled (e.g., directly electrically connected) with the first terminal of the additional first capacitor and having a second terminal coupled (e.g., directly electrically connected) with the second terminal of the additional first capacitor, and the one or more additional second inductors include a second inductor having a first terminal coupled (e.g., directly electrically connected) with the first terminal of the additional second capacitor and having a second terminal coupled (e.g., directly electrically connected) with the second terminal of the additional second capacitor.

Example 9 provides the electronic component of example 7, in which: the one or more additional first inductors include a first inductor and an additional first inductor, a first terminal of the first inductor is coupled (e.g., directly electrically connected) with the first terminal of the additional first capacitor, a second terminal of the first inductor is coupled (e.g., directly electrically connected) with a first terminal of the additional first inductor, a second terminal of the additional first inductor is coupled (e.g., directly electrically connected) with the second terminal of the additional first capacitor, the one or more additional second inductors include a second inductor and an additional second inductor, a first terminal of the second inductor is coupled (e.g., directly electrically connected) with the first terminal of the additional second capacitor, a second terminal of the second inductor is coupled (e.g., directly electrically connected) with a first terminal of the additional second inductor, and a second terminal of the additional second inductor is coupled (e.g., directly electrically connected) with the second terminal of the additional second capacitor.

Example 10 provides the electronic component of any one of examples 7-9, in which the additional first capacitor is a first variable capacitor and the additional second capacitor is a second variable capacitor.

Example 11 provides an electronic component (e.g., a distributed oscillator) that may include a plurality of distributed oscillator units. An individual distributed oscillator unit of the plurality of distributed oscillator units includes a transmission-line segment having a first end and a second end, a first oscillator coupled with the first end, a second oscillator coupled with the second end, a first circuit including one or more first inductors, in which the first circuit is coupled with the first end and the first oscillator, and a second circuit including one or more second inductors, in which the second circuit is coupled with the second end and the second oscillator.

Example 12 provides the electronic component of example 11, in which distributed oscillator units of the plurality of distributed oscillator units are coupled in series.

Example 13 provides the electronic component of example 11, in which: the plurality of distributed oscillator units includes a first distributed oscillator unit and a second distributed oscillator unit, and the first oscillator of the second distributed oscillator unit is coupled with the second oscillator of the first distributed oscillator unit.

Example 14 provides the electronic component of example 13, in which: the plurality of distributed oscillator units further includes a third distributed oscillator unit, and the first oscillator of the third distributed oscillator unit is coupled with the second oscillator of the second distributed oscillator unit.

Example 15 provides the electronic component of any one of examples 11-14, in which: the transmission-line segment further has a middle portion between the first end and the second end, the first circuit is coupled with the first end and the first oscillator by being coupled between (e.g., directly electrically connected with each of) the first oscillator and the middle portion, and the second circuit is coupled with the second end and the second oscillator by being coupled between (e.g., directly electrically connected with each of) the second oscillator and the middle portion.

Example 16 provides the electronic component of example 15, in which: the first circuit further includes a first capacitor having a first terminal coupled (e.g., directly electrically connected) with a negative signal branch of the transmission-line segment and having a second terminal coupled (e.g., directly electrically connected) with a positive signal branch of the transmission-line segment, and the second circuit further includes a second capacitor having a first terminal coupled (e.g., directly electrically connected) with the negative signal branch of the transmission-line segment and having a second terminal coupled (e.g., directly electrically connected) with the positive signal branch of the transmission-line segment.

Example 17 provides the electronic component of example 16, in which: the first capacitor is coupled (e.g., directly electrically connected) with the one or more first inductors, and the second capacitor is coupled (e.g., directly electrically connected) with the one or more second inductors.

Example 18 provides the electronic component of examples 16 or 17, in which: the one or more first inductors include a first inductor having a first terminal coupled (e.g., directly electrically connected) with the first terminal of the first capacitor and having a second terminal coupled (e.g., directly electrically connected) with the second terminal of the first capacitor, and the one or more second inductors include a second inductor having a first terminal coupled (e.g., directly electrically connected) with the first terminal of the second capacitor and having a second terminal coupled (e.g., directly electrically connected) with the second terminal of the second capacitor.

Example 19 provides the electronic component of examples 16 or 17, in which: the one or more first inductors include a first inductor and an additional first inductor, a first terminal of the first inductor is coupled (e.g., directly electrically connected) with the first terminal of the first capacitor, a second terminal of the first inductor is coupled (e.g., directly electrically connected) with a first terminal of the additional first inductor, a second terminal of the additional first inductor is coupled (e.g., directly electrically connected) with the second terminal of the first capacitor, the one or more second inductors include a second inductor and an additional second inductor, a first terminal of the second inductor is coupled (e.g., directly electrically connected) with the first terminal of the second capacitor, a second terminal of the second inductor is coupled (e.g., directly electrically connected) with a first terminal of the additional second inductor, and a second terminal of the additional second inductor is coupled (e.g., directly electrically connected) with the second terminal of the second capacitor.

Example 20 provides the electronic component of any one of examples 16-19, in which the first capacitor is a first variable capacitor and the second capacitor is a second variable capacitor.

Example 21 provides the electronic component of any one of examples 11-20, further including a plurality of channels, in which: a first distributed oscillator unit of the plurality of distributed oscillator units is proximate to a first channel of the plurality of channels, and a second distributed oscillator unit of the plurality of distributed oscillator units is proximate to a second channel of the plurality of channels.

Example 22 provides the electronic component of example 21, further including a PLL circuit, in which: a third distributed oscillator unit of the plurality of distributed oscillator units is proximate to the PLL circuit.

Example 23 provides the electronic component of any one of examples 21-22, in which the plurality of channels includes a horizontal polarization in-phase channel, a horizontal polarization quadrature channel, a vertical polarization in-phase channel, and a vertical polarization quadrature channel.

Example 24 provides the electronic component of example 23, in which each channel of the plurality of channels includes a digital-to-analog converter.

Example 25 provides the electronic component of examples 23 or 24, in which each channel of the plurality of channels includes an analog-to-digital converter.

Example 26 provides the electronic component of any one of examples 23-25, further including a plurality of optical modulators.

Example 27 provides the electronic component of any one of examples 1-26, in which the electronic component is a receiver of a communication system.

Example 28 provides the communication device of any one of examples 1-26, in which the electronic component is a transmitter of a communication system.

Example 29 provides the electronic component of any one of examples 1-26, in which the electronic component is a transceiver of a communication system.

Example 30 provides the electronic component of any one of examples 27-29, in which the communication system is an optical communication system.

Example 31 provides the electronic component of example 30, in which the optical communication system is a CPO system.

Example 32 provides the electronic component of example 30, in which the optical communication system is an OCI system.

Example 33 provides the electronic component of any one of examples 27-29, in which the communication system is an electrical communication system.

Example 34 provides the electronic component of example 33, in which the electrical communication system is a PCIe system or a SerDes system.

Example 35 provides the electronic component of example 33, in which the electrical communication system is an Ethernet backplane system.

Example 36 provides a communication device, including a plurality of components (e.g., components corresponding to individual channels of the communication device); and a distributed oscillator to provide clock signals to the plurality of components, wherein the distributed oscillator includes an electronic component of any one of examples 1-35, e.g., wherein the distributed oscillator includes a plurality of units that includes a first unit proximate to a first component of the plurality of components, and a second unit proximate to a second component of the plurality of components and coupled in series with the first unit, in which each of the first unit and the second unit includes a transmission line having a first end, a second end, and a portion between the first end and the second end, a first oscillator coupled with the first end, a second oscillator coupled with the second end, a first inductive matching circuit coupled between the first oscillator and the portion, and a second inductive matching circuit coupled between the second oscillator and the portion.

Example 37 provides the communication device of example 36, in which the communication device is a receiver of a communication system.

Example 38 provides the communication device of example 36, in which the communication device is a transmitter of a communication system.

Example 39 provides the communication device of example 36, in which the communication device is a transceiver of a communication system.

Example 40 provides the communication device of any one of examples 37-39, in which the communication system is an optical communication system.

Example 41 provides the communication device of example 40, in which the optical communication system is a CPO system.

Example 42 provides the communication device of example 40, in which the optical communication system is an OCI system.

Example 43 provides the communication device of any one of examples 37-39, in which the communication system is an electrical communication system.

Example 44 provides the communication device of example 43, in which the electrical communication system is a PCIe system.

Example 45 provides the communication device of example 43, in which the electrical communication system is an Ethernet backplane system.

Example 46 provides the communication device of example 43, in which the electrical communication system is a SerDes system.

Example 47 provides the communication device of any one of examples 36-46, further including a PLL circuit, in which the plurality of units further includes a third unit proximate to the PLL circuit and coupled in series with the second unit.

Example 48 provides a communication device that includes means for providing individual communication channels of the communication device; and means for providing clock signals to the individual communication channels, wherein the means for providing the clock signals includes an electronic component of any one of examples 1-35, e.g., wherein the means for providing the clock signals includes means for adjusting the electrical length of a transmission line of the means for providing the clock signals.

Example 49 provides the communication device of example 48, wherein the means for adjusting electrical length includes means for providing an inductive matching circuit at each end of the transmission line.

Example 50 provides the communication device of examples 48 or 49, further comprising means for providing functionality of any of examples 36-47.

The foregoing description of the illustrated embodiments, including the Abstract, is provided for illustrative purposes and is not intended to be exhaustive or to restrict the disclosure to the specific implementations shown. Although particular examples and embodiments are described herein, those skilled in the relevant art will recognize that numerous variations, modifications, and equivalent implementations are possible within the scope of the disclosure. Such modifications may be made in light of the detailed description provided above, without departing from the principles and spirit of the disclosure.

1. An electronic component, comprising:
a transmission line having a first end and a second end;
a first oscillator coupled with the first end;
a second oscillator coupled with the second end;
a first circuit coupled with the first oscillator and the first end; and
a second circuit coupled with the second oscillator and the second end,
wherein:
the first circuit includes a first capacitor having a first terminal coupled with a negative signal branch of the transmission line and having a second terminal coupled with a positive signal branch of the transmission line, and further includes one or more first inductors coupled with the first capacitor, and
the second circuit includes a second capacitor having a first terminal coupled with the negative signal branch of the transmission line and having a second terminal coupled with the positive signal branch of the transmission line, and further includes one or more second inductors coupled with the second capacitor.

2. The electronic component of claim 1, wherein:
the one or more first inductors include a first inductor having a first terminal coupled with the first terminal of the first capacitor and having a second terminal coupled with the second terminal of the first capacitor, and
the one or more second inductors include a second inductor having a first terminal coupled with the first terminal of the second capacitor and having a second terminal coupled with the second terminal of the second capacitor.

3. The electronic component of claim 1, wherein:
the one or more first inductors include a first inductor and an additional first inductor,
a first terminal of the first inductor is coupled with the first terminal of the first capacitor,
a second terminal of the first inductor is coupled with a first terminal of the additional first inductor,
a second terminal of the additional first inductor is coupled with the second terminal of the first capacitor,
the one or more second inductors include a second inductor and an additional second inductor,
a first terminal of the second inductor is coupled with the first terminal of the second capacitor,
a second terminal of the second inductor is coupled with a first terminal of the additional second inductor, and
a second terminal of the additional second inductor is coupled with the second terminal of the second capacitor.

4. The electronic component of claim 1, wherein the first capacitor is a first variable capacitor.

5. The electronic component of claim 1, wherein:
the transmission line, the first oscillator, the second oscillator, the first circuit, and the second circuit are portions of a first oscillator unit,
the electronic component further includes a second oscillator unit,
the second oscillator unit includes an additional transmission line, an additional first oscillator, an additional second oscillator, an additional first circuit, and an additional second circuit,
the additional transmission line has a first end, a second end, and a middle portion between the first end and the second end,
the additional first oscillator is coupled with the first end of the additional transmission line,
the additional second oscillator is coupled with the second end of the additional transmission line,
the additional first circuit is coupled between the additional first oscillator and the middle portion of the additional transmission line, and
the additional second circuit is coupled between the additional second oscillator and the middle portion of the additional transmission line.

6. The electronic component of claim 5, wherein:
the first oscillator of the second oscillator unit is coupled with the second oscillator of the first oscillator unit.

7. A distributed oscillator, comprising:
a transmission-line segment having a first end, a second end, and a middle portion between the first end and the second end;
a first oscillator coupled with the first end;
a second oscillator coupled with the second end;
a first inductive matching circuit coupled between the first oscillator and the middle portion; and
a second inductive matching circuit coupled between the second oscillator and the middle portion.

8. The distributed oscillator of claim 7, wherein:
the distributed oscillator includes a plurality of distributed oscillator units coupled in series, and
an individual distributed oscillator unit of the plurality of distributed oscillator units includes the transmission-line segment, the first oscillator, the second oscillator, the first inductive matching circuit, and the second inductive matching circuit.

9. The distributed oscillator of claim 7, wherein:
the distributed oscillator includes a plurality of distributed oscillator units coupled in series,
an individual distributed oscillator unit of the plurality of distributed oscillator units includes the transmission-line segment, the first oscillator, the second oscillator, the first inductive matching circuit, and the second inductive matching circuit,
the plurality of distributed oscillator units includes a first distributed oscillator unit and a second distributed oscillator unit, and
the first oscillator of the second distributed oscillator unit is coupled with the second oscillator of the first distributed oscillator unit.

10. The distributed oscillator of claim 9, wherein:
the plurality of distributed oscillator units further includes a third distributed oscillator unit, and
the first oscillator of the third distributed oscillator unit is coupled with the second oscillator of the second distributed oscillator unit.

11. The distributed oscillator of claim 7, wherein:
the first inductive matching circuit includes one or more first inductors, and
the second inductive matching circuit includes one or more second inductors.

12. The distributed oscillator of claim 11, wherein:
the first inductive matching circuit further includes a first capacitor having a first terminal coupled with a negative signal branch of the transmission-line segment and having a second terminal coupled with a positive signal branch of the transmission-line segment, and
the second inductive matching circuit further includes a second capacitor having a first terminal coupled with the negative signal branch of the transmission-line segment and having a second terminal coupled with the positive signal branch of the transmission-line segment.

13. The distributed oscillator of claim 12, wherein:
the first capacitor is coupled with the one or more first inductors, and
the second capacitor is coupled with the one or more second inductors.

14. The distributed oscillator of claim 12, wherein:
the one or more first inductors includes a first inductor having a first terminal coupled with the first terminal of the first capacitor and having a second terminal coupled with the second terminal of the first capacitor, and
the one or more second inductors include a second inductor having a first terminal coupled with the first terminal of the second capacitor and having a second terminal coupled with the second terminal of the second capacitor.

15. The distributed oscillator of claim 12, wherein:
the one or more first inductors includes a first inductor and an additional first inductor,
a first terminal of the first inductor is coupled with the first terminal of the first capacitor,
a second terminal of the first inductor is coupled with a first terminal of the additional first inductor,
a second terminal of the additional first inductor is coupled with the second terminal of the first capacitor,
the one or more second inductors include a second inductor and an additional second inductor,
a first terminal of the second inductor is coupled with the first terminal of the second capacitor,
a second terminal of the second inductor is coupled with a first terminal of the additional second inductor, and
a second terminal of the additional second inductor is coupled with the second terminal of the second capacitor.

16. The distributed oscillator of claim 7, further comprising:
a plurality of distributed oscillator units coupled in series; and
a plurality of channels,
wherein:
an individual distributed oscillator unit of the plurality of distributed oscillator units includes the transmission-line segment, the first oscillator, the second oscillator, the first inductive matching circuit, and the second inductive matching circuit,
a first distributed oscillator unit of the plurality of distributed oscillator units is proximate to a first channel of the plurality of channels, and
a second distributed oscillator unit of the plurality of distributed oscillator units is proximate to a second channel of the plurality of channels.

17. The distributed oscillator of claim 16, further comprising:
a phase-locked loop (PLL) circuit,
wherein:
a third distributed oscillator unit of the plurality of distributed oscillator units is proximate to the PLL circuit.

18. The distributed oscillator of claim 16, wherein the plurality of channels includes:
a horizontal polarization in-phase channel,
a horizontal polarization quadrature channel,
a vertical polarization in-phase channel, and
a vertical polarization quadrature channel.

19. A communication device, comprising:
means for providing individual communication channels of the communication device; and
means for providing clock signals to the individual communication channels, wherein the means for providing the clock signals includes means for adjusting electrical length of a transmission line of the means for providing the clock signals.

20. The communication device of claim 19, wherein the means for adjusting electrical length includes means for providing an inductive matching circuit at each end of the transmission line.

21. A communication device, comprising:
a first component;
a second component; and
a distributed oscillator comprising a plurality of units,
wherein the plurality of units includes:
a first unit proximate to the first component, and
a second unit proximate to the second component and coupled in series with the first unit, and wherein each of the first unit and the second unit includes:
a transmission line having a first end, a second end, and a portion between the first end and the second end,
a first oscillator coupled with the first end,
a second oscillator coupled with the second end,
a first circuit comprising one or more first inductors and coupled between the first oscillator and the portion, and
a second circuit comprising one or more second inductors and coupled between the second oscillator and the portion.

22. The communication device of claim 21, further comprising:
a third component; and
a phase-locked loop (PLL) circuit,
wherein the plurality of units further includes a third unit proximate to the PLL circuit and coupled in series with the second unit.
